(19) United States
(12) Patent Application Publication
(10) Pub. No.: US 2017/0081497 A1
(43) Pub. Date: Mar. 23, 2017

(54) ELECTRICALLY DISSIPATIVE ELASTOMER COMPOSITION COMPRISING CONDUCTIVE CARBON POWDER EMANATING FROM LIGNIN, A METHOD FOR THE MANUFACTURING THEREOF AND USE THEREOF

(71) Applicant: Stora Enso OYJ, Helsinki (FI)

(72) Inventors: Niklas Garoff, Hägersten (SE); Stephan Walter, Aachen (DE)

(21) Appl. No.: 15/310,523

(22) PCT Filed: May 12, 2015
(86) PCT No.: PCT/IB2015/053472

§ 371 Date: Nov. 11, 2016

(30) Foreign Application Priority Data
May 12, 2014 (SE) 1450554-9

(51) Int. Cl. C08K 3/04; H05K 9/00; D01F 9/17

(52) U.S. Cl. CPC C08K 3/04; D01F 9/17; H05K 9/0083; H05K 9/0079; C08K 2201/001

(57) ABSTRACT

The present invention relates to an elastic composition comprising a conductive carbon powder, a method for the manufacturing thereof and use thereof.

### FIELD OF INVENTION

The present invention relates to an elastomer composition comprising conductive carbon powder emanating from lignin. Further uses thereof are disclosed. Additionally a method for manufacturing said composition is disclosed.

### BACKGROUND

Conventional natural as well as synthetic rubbers are used as electrical insulators and prone to build-up of static electricity. This also applies to most commercial viable thermoplastic elastomers. The main applications for conductive elastomers are protection against electromagnetic interference (EMI) and electrostatic discharge (ESD), for example in flooring and conveyor belts. Further applications are in certain apparel, clothing, footwear, and such, where either electrostatic discharges pose a hazard or reduce comfort of wear. Conductive elastomers conventionally used today are made by blending a conductive material (metal powder, conductive carbon black, milled or chopped carbon fiber) with conventional base material (e.g. natural or synthetic rubbers or thermoplastic elastomers) to get a conductive or dissipative compound. The most common conductive material used is conductive carbon black. Conductive carbon black is produced by pyrolysis of cracker fuel oil rich in high boiling aromatic components to obtain crude carbon black. This is then post-treated to remove oxygen and organic impurities in order to increase electrical conductivity. Other options are based on metallic coatings or use of inherently conductive or dissipative polymers. Both of which have major limitations due to each application area.

Carbon black is produced by pyrolysing oil with fuel gas in a furnace. In the production of conductive carbon blacks, pyrolysis is followed by expensive post treatment steps to increase conductivity, notably steam exposure to increase the surface area and extraction to remove contaminants. Carbon blacks and especially conductive carbon blacks have a strongly negative impact on the environment and a high CO₂ footprint due to the fact that fossil raw materials are used in a highly energy intense production process.

A certain amount of conductive material—usually a carbon black—must be added to the base material in order to render the material conductive. For most conductive carbon blacks this so called percolation point is reached at about 20-30% addition level. The conductive material is usually much more expensive than the base material itself and a major cost item for conductive compounds. Another drawback is that the mechanical strength and ductility of the compound decreases at these addition levels. The mentioned inherently conductive or dissipative materials are usually unreasonably expensive for most applications. Metallized surfaces or coatings are due to the elastic behavior of the base material quickly worn off and prone to fail in their functionality.

There is thus a need for novel competitive high performing elastomeric compositions. It has surprisingly been found that powder made from carbonized lignin provides excellent electrical conductivity when mixed with a thermoplastic already at low addition levels. Surprisingly, carbonized lignin powder showed the same performance as highly conductive and expensive carbon blacks. Thus, the novel conductive elastomeric materials comprising carbonized lignin address the problems stated above. In addition, the carbonized lignin is based on a renewable feedstock and gives a lower CO₂ footprint to the conductive elastomer compared to established conductive materials.

### SUMMARY OF THE INVENTION

The present invention solves one or more of the above problems, by providing according to a first aspect a polymer composition comprising an electrically conductive carbon powder emanating essentially from lignin, and an elastic polymer material, or a combination of one or more thermoplastics and said material.

The present invention also provides according to a second aspect a method for the manufacturing of a composition according to a first aspect comprising mixing a conductive carbon powder with an elastic polymer material, or a combination of one or more thermoplastics and said material.

The present invention also provides according to a third aspect a polymer composition obtainable by a method according to the second aspect.

The present invention also provides according to a fourth aspect use of a polymer composition according to the first aspect or third aspect for protection against radio frequency interference (RFI), electromagnetic interference (EMI) and/or electrostatic discharge (ESD).

### DETAILED DESCRIPTION OF THE INVENTION

It is intended throughout the present description that the expression “lignin” embraces any lignin which may be used for making a conductive carbon powder. Examples on said lignin are, but are not limited to softwood lignin, hardwood lignin, lignin from one-year plants or lignins obtained through different fractionation methods such as, organosolv lignin or kraft lignin. The lignin may e.g. be obtained by using the process disclosed in EP 1794363.

It is intended throughout the present description that the expression “a conductive carbon powder” embraces a powderous matter which consists of 80% or more of carbon, with a capability of rendering e.g. thermoplastic, elastomeric or thermoset materials electrically dissipative, antistatic or conductive. Said thermoplastic or thermoset material may further be a polymer of fossil origin. Said powder may further be a substitute for carbon black obtained from fossil sources.

It is intended throughout the present description that the expression “electrically conductive carbon powder emanating essentially from lignin” embraces an electrically conductive carbon powder originating essentially from lignin, preferably emanating fully from lignin. This may also have it origin from an electrically conductive carbon intermediate product having the form of a powder or a shaped body such as, a wafer, sheet, bar, rod, film, filament or fleece. Further it may be manufactured in a method, thus also obtainable from said method, comprising the following steps:
a) thermal treatment of a lignin comprising compound to increase the carbon content to at least 80% to obtain an electrically conductive carbonized lignin intermediate product and
b) mechanical treatment of the electrically conductive carbonized lignin intermediate product to obtain a carbonized lignin powder which is electrically conductive, or
a method for manufacturing an electrically conductive carbon powder, comprising the following steps:
i) providing a lignin and at least one additive,
ii) mixing said components,
iii) shaping said mixture to form a shaped body,
iv) performing a thermal treatment of said shaped body in at least one step of which the last step comprises a temperature treatment up to about 2000° C. in inert atmosphere, thus providing a conductive carbonized intermediate product
v) pulverizing said conductive carbonized intermediate product, thus providing a conductive carbon powder or
a method for manufacturing a carbonized intermediate product in filament form, comprising the following steps:
vi) providing a lignin and at least one additive,
vii) mixing said components and melt spinning said mixture to a monofilament or multifilament bundle component,
viii) performing a thermal treatment of said shaped body in two steps of which the last step comprises a temperature ramp from room temperature to up to about 2000° C. in inert atmosphere thus providing a conductive carbonized intermediate product in filament form.

The conductive carbon may further be obtained at a temperature range in the second thermal step may also be from room temperature up to 1600° C., or up to 1200° C. or up to 1000° C. In the first thermal step, the temperature may be up to 300° C. There may also be a temperature ramp from room temperature to up to about 2000° C.

Also said carbon powder may be obtained as set out above but with the following modification where one or more steps as set out below may be optional:
Optional Step ii)—mixing of lignin with additives and water
Optional Step iii)—compressing/compacting to shaped body

It is intended throughout the present description that the expression “additive” embraces any additive that facilitates the manufacturing of a lignin-containing composition in e.g. melt-extrusion or melt-spinning for further processing to conductive carbonized lignin powder. Examples are, but are not limited to plasticizers (such as PEG, an example is PEG400), reactive agents that render lignin melt-extrudable such as aliphatic acids or lignin solvents. A lignin solvent may be an aprotic polar solvent, such as an aliphatic amide, such as dimethylformamide (DMF) or dimethylacetamide (DMAc), phthalic acid anhydride (PAA), a tertiary amine oxide, such as N-methylmorpholine-N-oxide (NMMO), dimethylsulfoxid (DMSO), ethylene glycol, di-ethylene glycol, low-molecular-weight poly ethylene glycol (PEG) having a molecular weight between 150 to 20.000 g/mol or ionic liquids or any combination of said solvents and liquids.

It is intended throughout the present description that the expression “thermoplastic” embraces any thermoplastic polymer or combinations of different thermoplastic polymers (which may be of fossil origin) that may be useful in the context of making a composition according to the first aspect of the invention whereby using a conductive carbon powder (which also includes contexts where carbon black is used). Said polymer may be, but is not limited to acrylates such as PMMA, PP (Polypropylene), PE (Polyethylene) such as HDPE (high density PE), MDPE (medium density PE), LDPE (low density PE), PA (Polyamide) such as nylon, PS (Polystyrene), polyvinylchloride (PVC), polysulfone, ether ketone or polytetrafluoroethylene (PTFE). The PE may further be cross-linked (PEX). It may further be co-polymers comprising two or more of said polymers or mixtures comprising two or more of said polymers.

It is intended throughout the present description that the expression “elastic polymer material” embraces elastic polymer material such as, but is not limited to, SOS (styrene olefin thermoelast), TPAE (ester ether thermoelast, such as HYTREL®)), TPS (styrene block copolymer), SBS (Styrene-Butadiene-Styrene, such as SEBS which is a sub-type of SBS), POE (Polyolefin elastomer), TPO (Thermoplastic polyolefin, which may be consisting of some fractions of two or more of PP, PE, filler, rubber), PVC/NBR (Poly(vinyl chloride) and nitrile rubber (or acrylonitrile butadiene rubber) mixtures)), MPR (Melt processable Rubber types), TPV (or TPE-V-thermoplastic elastomer-vulcanizates e.g. propylene-ethylene-diene terpolymer), TPU thermoplastic polyurethanes, COPE (Polyether-Ester Block Copolymer), COPA/PEBA (Polyether-Block-Amide Thermoplastic Elastomer) and TEO (thermoplastic Polyolefin Elastomer), natural or synthetic rubber (such as Styrene rubber (SBR), isoprene rubber (IR), butyl rubber (IIR), ethylenepropylene rubber (EPDM), nitrile rubber (NBR), chloroprene rubber (CR), urethane rubber (U), fluor rubber (FPM), chloro sulfonethylene rubber (CSM), acrylic rubber (ACM), epichlorohydrine rubber (ECO/CO), chloro ethylene rubber (CM), polysulfide rubber (T) and silicone rubber (Q)), latex or combinations thereof.

It is intended throughout the present description that the expression “thermoset” embraces any thermoset polymer (which may be of fossil origin) that may be useful in the context of making a composition according to the first aspect of the invention whereby using a conductive carbon powder (which also includes contexts where carbon black is used). Said polymer may be, but is not limited to polyurethanes, polyesters, phenol-formaldehyde, urea-formaldehyde, melamine, epoxy, cyanate esters, vulcanized rubber and polyimides. It may further be copolymers comprising two or more of said polymers or mixtures comprising two or more of said polymers.

According to a preferred embodiment of the first aspect of the invention the conductive carbon powder when compounded gives a percolation threshold in the polymer compound at 1-40% addition level.

According to a preferred embodiment of the first aspect of the invention the conductive carbon powder is present from 0.01 w % to 40 w % weight fraction of composition, preferably below 20 w %, more preferably below 10 w % and most preferred below 5 w %.

According to a preferred embodiment of the first aspect of the invention the conductive carbon powder when mixed provides that the composition is electrically dissipative, preferably providing a volume resistivity below 10̂12 [Ohm cm], most preferred from 10̂0-10̂11 [Ohm cm], especially preferred below 10̂6 [Ohm cm]. According to a preferred embodiment of the first aspect of the invention the conductive carbon powder when compounded lowers the volume resistivity of the polymer compound after the percolation point to 10⁰-10⁶ Ω·cm.

According to a preferred embodiment of the first aspect of the invention the conductive carbon powder when compounded provides anti-static properties, preferably it lowers the volume resistivity below 10̂12 Ohm*cm.

According to a preferred embodiment of the first aspect of the invention the conductive carbon powder when compounded provides anti-static properties, preferably it lowers the surface resistivity below 10̂12 Ohms/square.

According to a preferred embodiment of the first aspect of the invention the conductive carbon powder when compounded lowers achieves conductivity, wherein preferably the volume resistivity is below 10̂6 Ohm*cm, most preferred from 10̂ to 10̂6 [Ohm cm].

According to a preferred embodiment of the fourth aspect of the invention the use is in wire and/or cables, electrically insulating materials, seals, gaskets, piping, lining, bands, belts, extrudates, profiles, foams, anti-static flooring, elastic coatings on surfaces, pouches, packaging, safety applications, foot wear (such as in shoe soles and heels), flooring and conveyor belts, apparel, clothing, and such where either electrostatic discharges pose a hazard or reduce comfort of wear, or in equipment used in operating theatres. Said apparel and clothing may also be used in operating theatres.

The method according to the second aspect may involve extrusion, compounding, mixing and subsequent processing, in situ modification, curing steps, reheating and shaping. Said method may also involve the use of additional coupling agents, or compatibilizers.

When it comes to the composition according to the first aspect said composition may comprise a carbon powder emanating from the following:
Pure lignin (not completely dry)
Pure lignin (completely dried)
Dried lignin with 10% PEG Undried (approx. 95% dry) lignin with 10% PEG
Undried (approx. 95% dry) lignin with 10% DMSO
Undried (approx. 95% dry) lignin with 5% PEG and 5% DMSO

Thus the conductive carbon powder may be used in elastic material systems with the effect of altering electrical properties rendering the composition electrically conductive, alternatively altering the electrical properties for the protection against discharge of static electricity, or alternatively altering the electrical properties for the use of shielding against electromagnetic interference and/or radio frequency interference

Preferred features of each aspect of the invention are as for each of the other aspects mutatis mutandis. The prior art document(s) mentioned herein are incorporated to the fullest extent permitted by law. The invention is further described in the following examples, together with the appended figures, which do not limit the scope of the invention in any way. Embodiments of the present invention are described as mentioned in more detail with the aid of examples of embodiments, together with the appended figures, the only purpose of which is to illustrate the invention and are in no way intended to limit its extent.

### FIGURES

FIG. 1 discloses volume resistivity of compounds comprised of PP, polypropylene, (HP 561R from Lyondell Basell) and 5% respectively 10% of the conductive carbon powder described in this invention. For comparison percolation curves are shown for reference compositions comprising PP and three different commercial conductive carbon blacks, respectively.

FIG. 2 discloses a comparison of volume resistivity of compressed carbon powder (applied pressure 31 MPa).

FIG. 3 discloses a comparison of volume resistivity of carbonized fibers.

### EXAMPLES

### Examples on Lignin-Containing Compound in Form of a Shaped Body

### Example 1

A fiber was melt-spun from a mixture comprising of 88 w % softwood Kraft lignin, 7 w % Phthalic anhydride acid and 5 w % DMSO (97% purity, Sigma-Aldrich) using a laboratory twin-screw extruder with a single capillary (DSM Xplore micro-compounder). The obtained lignin-containing compound had the form of a filament with a diameter of 150 μm.

### Example 2

The mixture from example 1 was extruded with a laboratory twin screw extruder (KEDSE 20/40″ from Brabender GmbH & CO. KG) using a multifilament die with 62 capillaries. The obtained lignin-containing compound had the form of a multi-filament bundle with a single filament diameter of 72 μm.

### Example 3

A mixture comprising 90 w % softwood lignin and 10% PEG 400 (Polyethylene Glycol from Sigma-Aldrich with a molecular weight of 400 Da) was prepared.

The mixture was extruded on a laboratory twin screw extruder using a die with 62 capillaries. The obtained lignin-containing compound had the form of a multi-filament bundle with a single filament diameter of 90 μm.

### Example 4

A mixture was prepared as described in example three and put in a flat metal tube. Pressure was applied using a piston and as a result the lignin-containing compound attained the shape of a wafer.

### Examples on Conductive Carbon Intermediate Products

### Example 5

The lignin-containing filament from example 1 was converted in a two-step thermal treatment to obtain a conductive carbon intermediate product. In a first step the filament was heated in air from room temperature to 250° C. with a varying heating rate of between 0.2° C./min and 5° C./min and then heated in the second step in nitrogen from room temperature to 1600° C. with a heating rate of 1° C./min. The obtained conductive carbon intermediate product had the shape of a filament with a diameter of about 60 μm and yielded an electrical volume resistivity of 1.4×10̂−3 Ohm*cm. Volume resistivity was measured using a LCR meter.

### Example 6

The obtained spun filaments from example 2 where heat-treated in the same manner as described in example 5. The resulting carbonized multifilaments had a diameter of about 80 μm and yielded an electrical volume resistivity of 0.5×10̂−3 Ohm*cm.

### Example 7

The obtained filaments from example 3 were where heat-treated in the same manner as described in example 5. The resulting carbonized multifilaments had a diameter of about 75 μm and yielded an electrical volume resistivity of 0.6×10̂−3 Ohm*cm.

### Example 8

The obtained filaments from example 3 were heat-treated according to the following steps. In a first step the filament was heated in air from room temperature to 250° C. with a varying heating rate between 0.2° C./min and 5° C./min and then heated in the second step in nitrogen from room temperature to 1000° C. with a heating rate of 2° C./min. The obtained carbonized fiber yielded an electrical volume resistivity of 0.72×10̂−3 Ohm*cm.

### Example 9

The obtained filaments from example 3 were heat-treated according to the following steps. In a first step the filament was heated in air from room temperature to 250° C. with a varying heating rate between 0.2° C./min and 5° C./min and then heated in the second step in nitrogen from room temperature to 1200° C. with a heating rate of 2° C./min. The obtained carbonized fiber yielded an electrical volume resistivity of 0.33×10̂−3 Ohm*cm.

### Example 10

The obtained filaments from example 3 were heat-treated according to the following steps. In a first step the filament was heated in air from room temperature to 250° C. with a varying heating rate between 0.2° C./min and 5° C./min and then heated in the second step in nitrogen from room temperature to 1400° C. with a heating rate of 2° C./min. The obtained carbonized fiber yielded an electrical volume resistivity of 0.23×10̂−3 Ohm*cm.

### Example 11

The obtained filaments from example 3 were heat-treated according to the following steps. In a first step the filament was heated in air from room temperature to 250° C. with a varying heating rate between 0.2° C./min and 5° C./min and then heated in the second step in nitrogen from room temperature to 1600° C. with a heating rate of 2° C./min. The obtained carbonized fiber yielded an electrical volume resistivity of 0.54×10̂−3 Ohm*cm.

### Example 12

The wafer from example 4 was heat treated in nitrogen atmosphere by increasing temperature from room temperature to 1600° C. at a heating rate of 1° C./min to obtain a carbonized wafer.

### Examples on Conductive Carbon Powder

### Example 13

The carbonized wafer from example 12 was manually crushed utilizing a laboratory mortar to obtain a conductive carbonized lignin powder.

### Examples on Conductive Polymer Compositions

### Example 14

The conductive carbonized lignin powder from example 14 was compounded into a polypropylene matrix (HP 561R from Lyondell

Basell) using a DSM Xplore micro-compounder. The MFR was 25 g/10 min (@230° C./2.16 kg/10 min). The composition consisted of 95 w % polypropylene and 5 % of conductive carbonized lignin powder. The extruded strands showed a volume resistivity of 5.2×10̂5 Ohm*cm, which was many magnitudes lower than the volume resistivity of pure PP, reported in the literature, about 1×10̂17 Ohm*cm (Debowska, M. et. al.: Positron annihilation in carbon black-polymer composites, Radiation Physics and Chemistry 58 (2000), H. 5-6, S. 575-579). This example showed that the conductive carbonized lignin powder from example 13 was in fact electrically conductive.

### Example 15

The conductive carbon powder from example 14 was compounded into a Polypropylene matrix (HP 561R from Lyondell Basell) using a DSM Xplore micro-compounder. The composition consisted of 90 w % (PP) and 10% conductive carbonized lignin powder. The extruded strands yielded a volume resistivity of 2.6×10̂5 Ohm*cm.

### Examples Including Reference Conductive Polymer Compositions

### Example 16

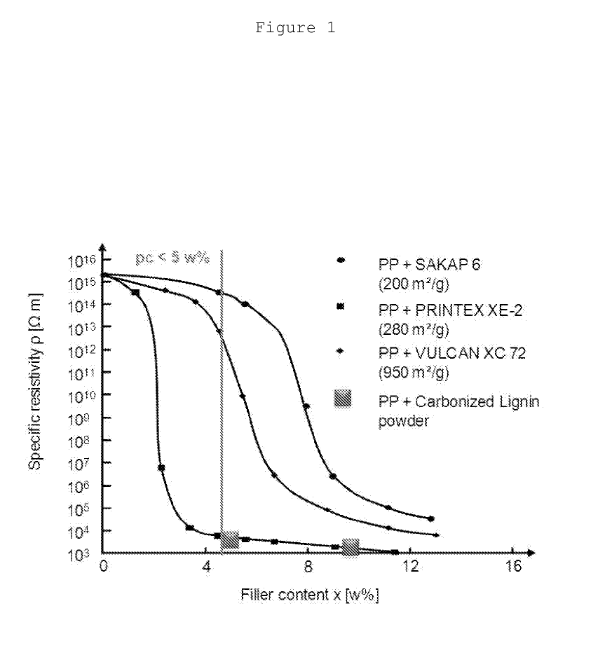

FIG. 1 reflects literature data (Debowska, M. et. al.: Positron annihilation in carbon black-polymer composites, Radiation Physics and Chemistry 58 (2000), H. 5-6, S. 575-579) regarding volume resistivity of conductive polymer compositions comprising different commercial conductive carbon blacks. The commercial carbon blacks were SAPAC-6 (from CarboChem), Printex XE-2 (from Degussa) and Vulcan XC-72 (Cabot).

FIG. 1 discloses also, additionally, volume resistivity of compositions comprising PP (HP 561R from Lyondell Basell) and 5% and 10%, respectively, of conductive carbon powder described above.

The figure shows that conductive carbonized lignin powder provided by the present invention has at least the same conductivity performance as the best commercial carbon black (Printex XE-2).

### Example 17

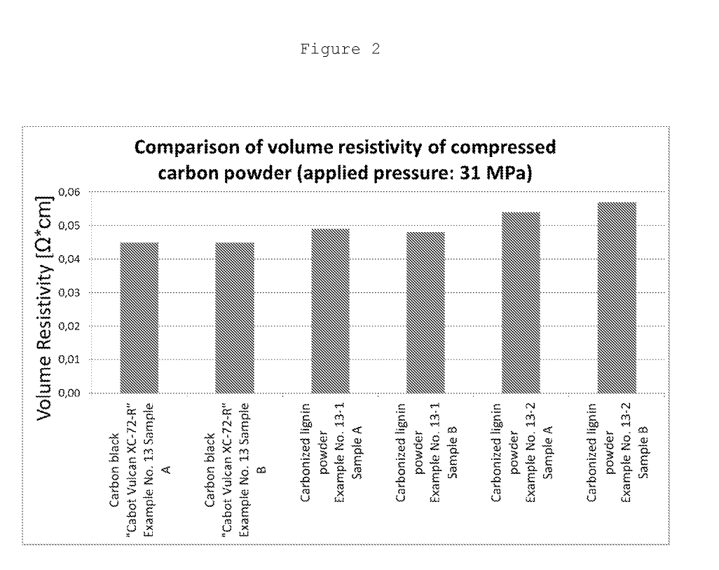

In order to measure the electrical conductivity of the powder samples, the powder was filled into a hollow cylinder. This cylinder was made of non-conductive PMMA which was cleaned thoroughly between each measurement. The inner diameter was 5 mm. At the bottom of the cylinder there was a gold plated copper plate as a base electrode. The second electrode was a copper stamp which was also gold plated and formed the second electrode. The stamp was then inserted into the cylinder thus slowly compressing the powder. Through a force measurement and online position measurement the applied pressure as well as the volume within the powder filled chamber was plotted. Through applying a DC voltage to the two electrodes the absolute resistance could be measured. Together with the documented position of the stamp a volume resistivity could be calculated. In order to compare various samples with potentially varying specific volumes the resistivity values could only be compared at equal pressure levels. In the presented results the chambers were filled with powder and compressed to the maximal pressure of 31 MPa. The measured value is indicated in FIG. 2.

The results presented in the figure clearly state that the lignin based carbonized powders (CLP) exhibit the same conductivity/resistivity performance as the commercially available grade of Cabot (Cabot Vulcan XC-72-R).

In the figure:

Example 31-1=Example 13 as mentioned above

Example 13-2=Example 13, but not manually crushed with a lab mortar but cryo milled.

### Example 18

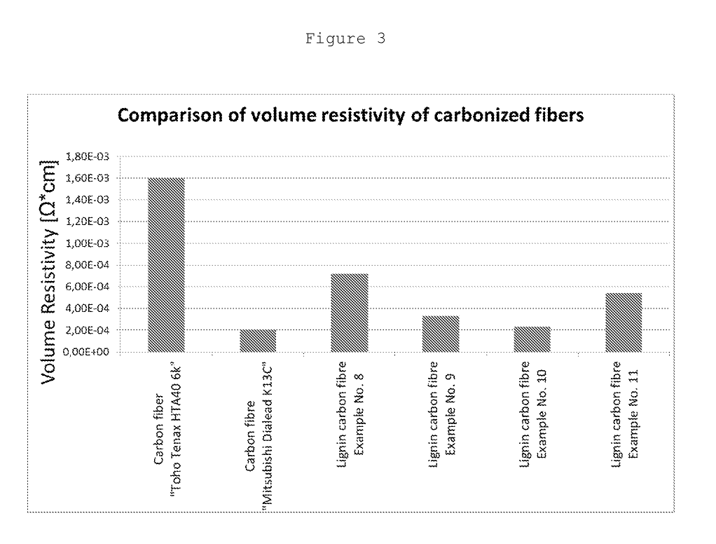

The products in examples 8-11 set out above earlier was also compared with commercial grade carbon fibres (Toho Tenax HTA40 6k and Mitsubishi Dialead K13C, respectively—their values were taken from a product sheet and the internet, respectively). The results are given in FIG. 3.

Various embodiments of the present invention have been described above but a person skilled in the art realizes further minor alterations, which would fall into the scope of the present invention. The breadth and scope of the present invention should not be limited by any of the above-described exemplary embodiments, but should be defined only in accordance with the following claims and their equivalents. For example, any of the above-noted compositions or methods may be combined with other known methods. Other aspects, advantages and modifications within the scope of the invention will be apparent to those skilled in the art to which the invention pertains.

1. A polymer composition comprising an electrically conductive carbon powder emanating essentially from lignin, and an elastic polymer material, or a combination of one or more thermoplastics and said material.

2. A polymer composition according to claim 1 wherein the elastic polymer material is
SOS (Styrene olefin thermoelast), TPAE (Ester ether thermoelast), TPS (styrene block copolymer), SBS (Styrene-Butadiene-Styrene), POE (Polyolefin elastomer), TPO (Thermoplastic polyolefin), PVC/NBR (Poly(vinyl chloride) and nitrile rubber (or acrylonitrile butadiene rubber) mixtures)), MPR (Melt processable Rubber types), TPV (thermoplastic elastomer-vulcanizates), TPU (thermoplastic polyurethanes), COPE (Polyether-Ester Block Copolymer), COPA/PEBA (Polyether-Block-Amide Thermoplastic Elastomer), TEO (thermoplastic Polyolefin Elastomer), natural or synthetic rubber, such as styrene rubber (SBR), isoprene rubber (IR), butyl rubber (IIR), ethylene propylene rubber (EPDM), nitrile rubber (NBR), chloroprene rubber (CR), urethane rubber (U), fluor rubber (FPM), chloro sulfonethylene rubber (CSM), acrylic rubber (ACM), epichlorohydrine rubber (ECO/CO), chloro ethylene rubber (CM), polysulfide rubber (T) and silicone rubber (Q)), latex or combinations thereof.

3. A polymer composition according to claim 1 wherein the conductive carbon powder when mixed gives a percolation threshold in the polymer compound at 1-40% addition level.

4. A polymer composition according to claim 1 wherein the conductive carbon powder is present from 0.01 w % to 40 w % weight fraction of composition.

5. A polymer composition according to claim 1 wherein the conductive carbon powder when compounded provides that the composition is electrically dissipative, providing a volume resistivity below 10̂12 [Ohm cm].

6. A polymer composition according to claim 1 wherein the conductive carbon powder when compounded lowers the volume resistivity of the polymer compound after the prelocation point to 100-106 Ω·cm.

7. A polymer composition according to claim 1 wherein the conductive carbon powder when compounded provides anti-static properties, lowering the volume resistivity below 10̂12 Ohm*cm.

8. A polymer composition according to claim 1 wherein the conductive carbon powder when compounded provides anti-static properties, lowering the surface resistivity below 10̂12 Ohms/square.

9. A polymer composition according to claim 1 wherein the conductive carbon powder when compounded lowers achieves conductivity, wherein the volume resistivity is below 10̂6 Ohm*cm.

10. A method for the manufacturing of a composition according to claim 1 comprising mixing a conductive carbon powder with an elastic polymer material, or a combination of one or more thermoplastics and said material.

11. A polymer composition obtainable by a method according to claim 10.

12. (canceled)

13. (canceled)

14. A polymer composition according to claim 1 wherein the conductive carbon powder is present below 20 w % weight fraction of composition.

15. A polymer composition according to claims 1 wherein the conductive carbon powder is present below 10 w % weight fraction of composition.

16. A polymer composition according to claim 1 wherein the conductive carbon powder is present below 5 w % weight fraction of composition.

17. A polymer composition according to claim 1 wherein the conductive carbon powder when compounded provides that the composition is electrically dissipative, providing a volume resistivity from 10̂0-10̂11 [Ohm cm].

18. A polymer composition according to claim 1 wherein the conductive carbon powder when compounded provides that the composition is electrically dissipative, providing a volume resistivity below 10̂6 Ohm*cm.

19. A polymer composition according to claim 1 wherein the conductive carbon powder when compounded lowers achieves conductivity, wherein the volume resistivity is from 10̂0 to 10̂6 [Ohm cm].
